(19) United States
(12) Patent Application Publication
(10) Pub. No.: US 2025/0343608 A1
(43) Pub. Date: Nov. 6, 2025

(54) SIGNAL RECEPTION DEVICE, IC, AND ELECTRIC DEVICE

(71) Applicant: ROHM Co., LTD., Kyoto (JP)

(72) Inventor: Takayuki Sudo, Kyoto (JP)

(21) Appl. No.: 19/174,735

(22) Filed: Apr. 9, 2025

(30) Foreign Application Priority Data
May 2, 2024 (JP) 2024-074780

(51) Int. Cl. H04B 17/29; G01R 31/28; G01R 31/3187; H04B 17/21

(52) U.S. Cl. CPC H04B 17/297; G01R 31/2856; G01R 31/3187; H04B 17/22

(57) ABSTRACT

Provided is a signal reception device including a processing circuit that outputs a processed signal obtained by applying predetermined processing to a received signal, a function block that receives the processed signal and executes processing determined on the basis of the processed signal, and a self-test circuit that outputs a test signal to the processing circuit and makes defective or non-defective state determination according to the signal output from the processing circuit.

### CROSS REFERENCE TO RELATED APPLICATIONS

This application claims priority benefit of Japanese Patent Application No. JP 2024-074780 filed in the Japan Patent Office on May 2, 2024. Each of the above-referenced applications is hereby incorporated herein by reference in its entirety.

### BACKGROUND

The present disclosure relates to a signal reception device and relates to an integrated circuit (IC) and an electric device including the signal reception device.

In related art, a signal transmission device which transmits a signal includes a filter for masking a noise component contained in the signal (see Japanese Patent Laid-open No. 2023-52304, for example).

Moreover, there is a signal transmission device configured to process a received signal and to then output the processed signal to an outside.

### BRIEF DESCRIPTION OF THE DRAWINGS

FIG. 1 is a block diagram for illustrating a configuration of a signal reception device;

FIG. 2 is a graph for illustrating states of signals in a Schmitt trigger circuit;

FIG. 3 is a diagram for illustrating states of the signal reception device at the time of execution of test processing;

FIG. 4 is a flowchart for illustrating the test processing;

FIG. 5 is a graph for illustrating a state of each signal when a filter circuit is in a non-defective state;

FIG. 6 is a graph for illustrating the state of each signal when the filter circuit is in a defective state;

FIG. 7 is a graph for illustrating the state of each signal in a case in which a state is determined to be in a defective operation state in the signal reception device;

FIG. 8 is a diagram for illustrating the states of the signal reception device according to a modification example; and

FIG. 9 is a diagram for illustrating a configuration of an example of an electric device including the signal reception device.

### DETAILED DESCRIPTION

A description is now given of an embodiment of the present disclosure with reference to the drawings.

### <Signal Reception Device 100>

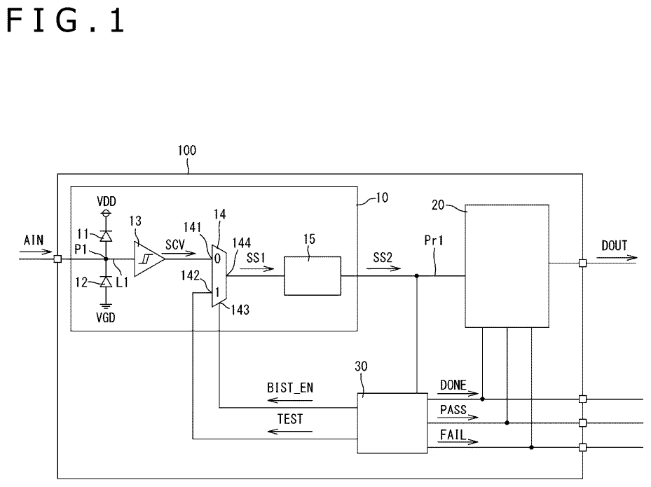

FIG. 1 is a block diagram for illustrating a configuration of a signal reception device 100. The signal reception device 100 illustrated in FIG. 1 receives an input signal AIN, executes processing according to the input signal AIN, and outputs a result of the processing as an external output signal DOUT. In the signal reception device 100, for example, the input signal AIN is an analog signal, and the external output signal DOUT is a digital signal. As illustrated in FIG. 1, the signal reception device 100 includes a processing circuit 10, a function block 20, and a self-test circuit 30. Note that the signal reception device 100 may be formed of one functional IC or may have a configuration of a combination of a plurality of functional ICs. Moreover, the signal reception device 100 may have such a configuration as to be built into a part of an IC which can implement a plurality of functions.

As illustrated in FIG. 1, the processing circuit 10 receives the input signal AIN and generates a processed signal SS2. The processing circuit 10 includes a first diode 11, a second diode 12, a Schmitt trigger circuit 13, a switching circuit 14, and a filter circuit 15.

The first diode 11 and the second diode 12 are serially connected to each other. Moreover, the anode of the first diode 11 and the cathode of the second diode 12 are connected to each other at a connection point P1. Further, the cathode of the first diode 11 is connected to a power supply terminal to which a power supply voltage VDD is applied. In addition, the anode of the second diode 12 is connected to a ground terminal to which a ground voltage VGD is applied.

An input line L1 is connected to the connection point P1 between the anode of the first diode 11 and the cathode of the second diode 12. The input signal AIN is input to the connection point P1 via the input line L1. A voltage clamp circuit is formed of the first diode 11 and the second diode 12. When the first diode 11 and the second diode 12 are diodes having the same configuration, and hence, the forward voltage drop is V1, the voltage level of the input signal AIN is limited to a range equal to or higher than VGD+V1 and equal to or lower than VDD+V1 by the voltage clamp circuit.

The Schmitt trigger circuit 13 has a first threshold value Th1 and a second threshold value Th2. The Schmitt trigger circuit 13 outputs a converted signal SCV according to the voltage level of the input signal AIN. The converted signal SCV is a digital voltage signal which takes any one value of a high level and a low level lower than the high level in voltage level.

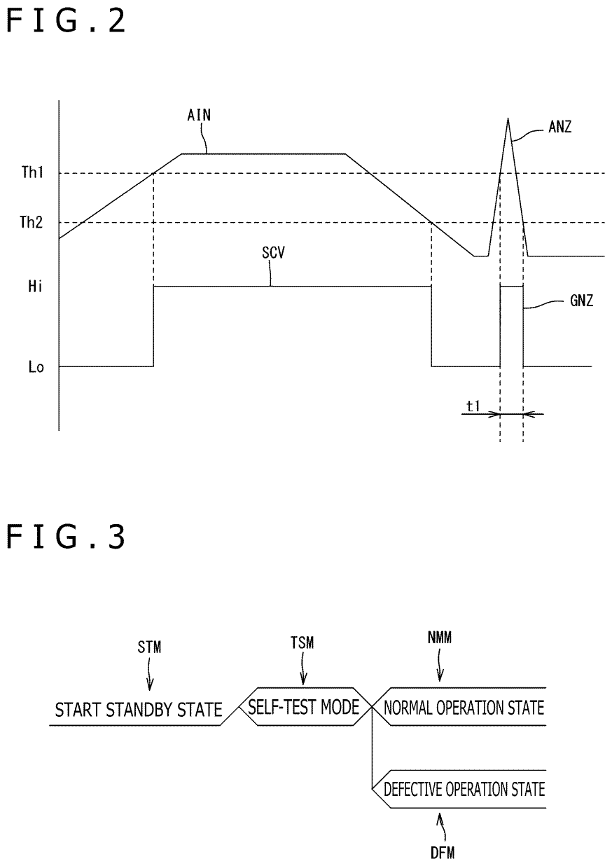

FIG. 2 is a diagram for illustrating states of the signals in the Schmitt trigger circuit 13. As illustrated in FIG. 2, in the Schmitt trigger circuit 13, the converted signal SCV switches from the low level to the high level when the voltage level of the input signal AIN exceeds the first threshold value Th1. Moreover, in the Schmitt trigger circuit 13, the converted signal SCV switches to the low level when the voltage level of the input signal AIN falls below the second threshold value Th2 in the state in which the converted signal SCV at the high level is output.

Through use of the Schmitt trigger circuit 13, the Schmitt trigger circuit 13 continues to output the converted signal SCV at the high level until the voltage level of the input signal AIN falls below the second threshold value Th2 after the voltage level once exceeds the first threshold value Th1. Moreover, the converted signal SCV is not switched to the high level as long as the voltage level of the input signal AIN does not exceed the first threshold value Th1 even when the voltage level exceeds the second threshold value Th2 in the state in which the Schmitt trigger circuit 13 outputs the converted signal SCV at the low level. The Schmitt trigger circuit 13 is a circuit configured to convert the input signal AIN to the digital converted signal SCV. The Schmitt trigger circuit 13 can stably output the converted signal SCV even when the voltage level of the input signal AIN fluctuates up and down within the certain range.

That is, the Schmitt trigger circuit 13 continues to output the converted signal SCV at the high level even when the voltage level of the input signal AIN falls below the first threshold value Th1 as long as the voltage level of the input signal AIN is a level higher than the second threshold value Th2 in a case in which the converted signal SCV at the high level is once output. Moreover, the Schmitt trigger circuit 13 continues to output the converted signal SCV at the low level even when the voltage level of the input signal AIN exceeds the second threshold value Th2 as long as the voltage level of the input signal AIN is a level lower than the first threshold value Th1 in a case in which the Schmitt trigger circuit 13 outputs the converted signal SCV at the low level. The Schmitt trigger circuit 13 can stably output the converted signal SCV through the provision of the two threshold values even when the voltage level of the input signal AIN fluctuates.

The converted signal SCV being the output of the Schmitt trigger circuit 13 is input to the switching circuit 14. The switching circuit 14 is a circuit which selects one of input signals and then outputs the selected signal. The switching circuit 14 can include a multiplexer circuit.

The switching circuit 14 has three input terminals 141, 142, and 143 and one output terminal 144. The input terminal 141 is connected to output of the Schmitt trigger circuit 13 and, to the input terminal 141, the converted signal SCV is input. Moreover, to the input terminal 142, a test signal TEST output from the self-test circuit 30 and described later is input. Further, to the input terminal 143, a test execution signal BIST_EN output from the self-test circuit 30 and described later is input. From the output terminal 144, an internal signal SS1 is output.

In the switching circuit 14, on the basis of the test execution signal BIST_EN input to the input terminal 143, the signal input to the input terminal 141 or the input terminal 142 is output, as the internal signal SS1, from the output terminal 144. Note that the test execution signal BIST_EN is a signal which takes the high level, that is, “1” or the low level, that is, “0.” In the switching circuit 14, when the test execution signal BIST_EN at the low level is input to the input terminal 143, the input terminal 141 is selected, and the input converted signal SCV is output as the internal signal SS1. Moreover, when the test execution signal BIST_EN at the high level is input to the input terminal 143, the input terminal 142 is selected, and the input test signal TEST is output as the internal signal SS1.

As illustrated in FIG. 2, noise called glitch noise ANZ is sometimes contained in the input signal AIN. The glitch noise ANZ is a signal in a pulse form which occurs in a short time due to, for example, a response delay caused by a wiring length and a variation in a reaction speed of an element. The glitch noise ANZ is sometimes converted by the Schmitt trigger circuit 13 and is then output in the pulse form. The glitch noise GNZ in the pulse form is a signal which is not permitted in terms of design and may possibly cause an erroneous operation of the function block 20.

Thus, the processing circuit 10 includes the filter circuit 15 configured to remove the glitch noise GNZ in the pulse form. The internal signal SS1 output from the switching circuit 14 is input to the filter circuit 15.

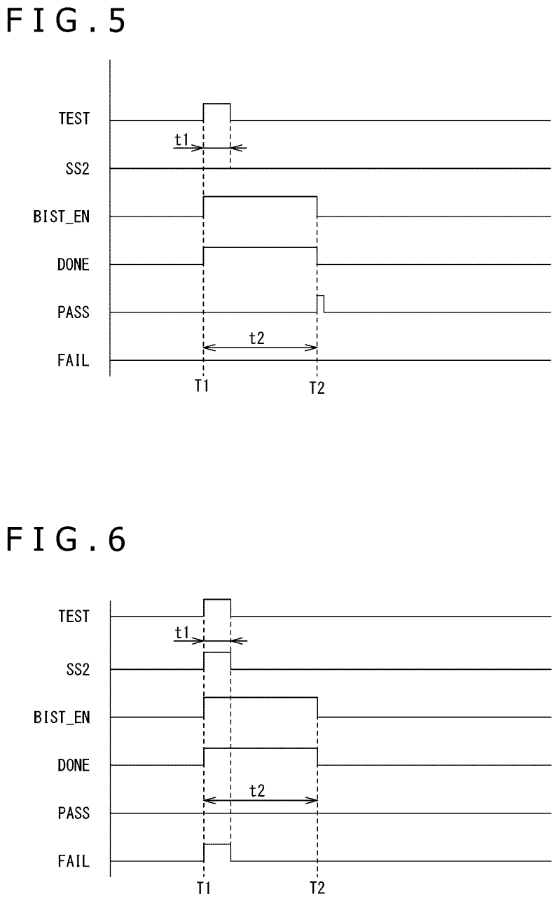

The glitch noise GNZ in the pulse form has a short time t1 (hereinafter referred to as a pulse width t1) from the rise to fall (see FIG. 5). Thus, the filter circuit 15 operates to remove, as the glitch noise GNZ, a pulse signal equal to or narrower than the pulse width t1 contained in the internal signal SS1. Note that the pulse width t1 is a value determined on the basis of a wiring pattern, a circuit configuration, and an element configuration, for example. The pulse width t1 may be configured to be set in advance or to be variable.

As described above, in the switching circuit 14, the internal signal SS1 having the same wave length as that of the test signal TEST is output from the output terminal 144 when the test execution signal BIST_EN is at the high level. The internal signal SS1 output from the output terminal 144 is input to the filter circuit 15.

### <Function Block 20>

The function block 20 is connected to the output terminal of the filter circuit 15 via a wire Pr1. The glitch noise GNZ in the pulse form is removed, in the filter circuit 15, from the internal signal SS1 input from the input terminal of the filter circuit 15, and the input signal SS1 is then input as the processed signal SS2 to the function block 20 via the wire Pr1. The function block 20 outputs the external output signal DOUT according to the processed signal SS2 from the filter circuit 15. The external output signal DOUT can include a signal for controlling an operation of an external device, not illustrated.

### <Self-Test Circuit 30>

The self-test circuit 30 is a circuit configured to check the operation of the filter circuit 15. The self-test circuit 30 is connected to the switching circuit 14, the wire Pr1, and the function block 20. The self-test circuit 30 supplies the test signal TEST to the input terminal 142 of the switching circuit 14. Moreover, the self-test circuit 30 supplies the test execution signal BIST_EN to the input terminal 143 of the switching circuit 14.

As illustrated in FIG. 5, the test signal TEST output from the self-test circuit 30 is a signal similar to the glitch noise GNZ in the pulse form generated in the signal reception device 100. When the glitch noise GNZ is a pulse signal rising from the low level to the high level, the self-test circuit 30 supplies, as the test signal TEST, a pulse signal having the pulse width t1 to the input terminal 142 of the switching circuit 14.

The test execution signal BIST_EN is a signal which takes the binary values being the high level and the low level. The self-test circuit 30 executes a test for the filter circuit 15 at a specific timing whose details are described later. The self-test circuit 30 supplies the test execution signal BIST_EN at the low level to the input terminal 143 of the switching circuit 14 when the self-test circuit 30 does not execute the test for the filter circuit 15, for example, at the time of a normal state. Moreover, the self-test circuit 30 supplies the test execution signal BIST_EN at the high level to the input terminal 143 of the switching circuit 14 in a case in which the test for the filter circuit 15 is to be executed.

The self-test circuit 30 is connected to the wire Pr1 and acquires the processed signal SS2 being the output signal from the filter circuit 15 when the test for the filter circuit 15 is being executed. The self-test circuit 30 may be configured not to receive a signal input when the test for the filter circuit 15 is not being executed or may be configured to employ a switching element or another element not to input the signal.

The self-test circuit 30 determines whether or not the filter circuit 15 can certainly remove the glitch noise according to the input processed signal SS2. Details of the operation of the self-test circuit 30 are described later. Moreover, the self-test circuit 30 outputs a test execution signal DONE, a non-defective state notification signal PASS, and a defective state notification signal FAIL to an external device such as a control circuit, not illustrated, which operates a system including the signal reception device 100.

Note that the test execution signal DONE, the non-defective state notification signal PASS, and the defective state notification signal FAIL may be input to the function block 20. The function block 20 may be configured to receive the processed signal SS2 when the test execution signal DONE and the non-defective state notification signal PASS are received.

The signal reception device 100 has the configuration described above. With reference to the drawings, a description is now given of an operation of the signal reception device 100.

### <Operation of Signal Reception Device 100>

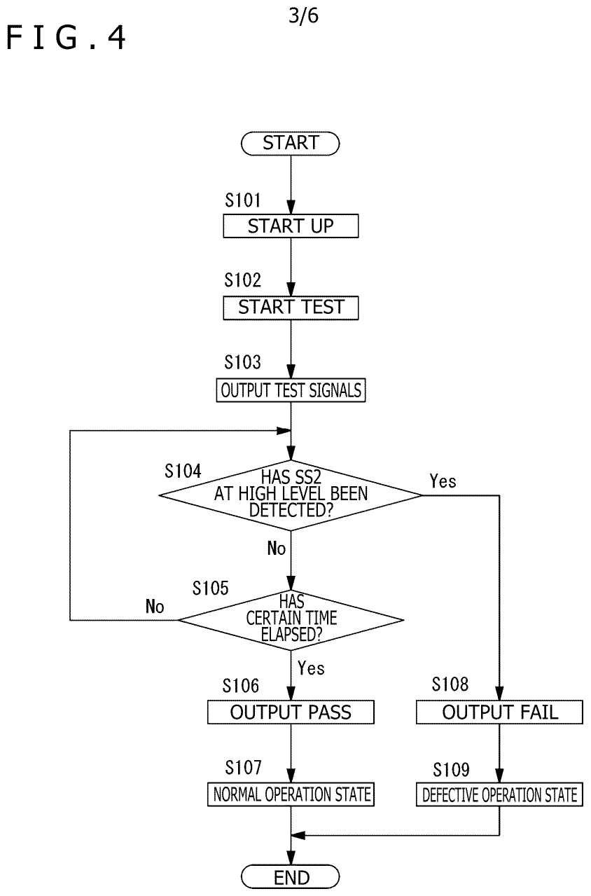

FIG. 3 is a diagram for illustrating states of the signal reception device 100 at the time of execution of test processing. FIG. 4 is a flowchart for illustrating the test processing. FIG. 5 is a graph for illustrating a state of each signal when the filter circuit 15 is in the non-defective state. FIG. 6 is a graph for illustrating the state of each signal when the filter circuit 15 is in the defective state.

In the signal reception device 100, in the state in which the input signal AIN is input, the glitch noise GNZ being the glitch noise ANZ converted into the pulse form is removed by the filter circuit 15, and the processed signal SS2 is supplied to the function block 20. In the signal reception device 100, it is preferred that the filter circuit 15 accurately remove the glitch noise GNZ while the input signal AIN is input. Thus, in the signal reception device 100, the self-test circuit 30 executes a test of the filter circuit 15, that is, an operation check therefor.

As illustrated in FIG. 3 and FIG. 4, when the signal reception device 100 is started up from a start standby state STM (Step S101), the signal reception device 100 transitions to a test mode TSM (Step S102). The self-test circuit 30 recognizes that the signal reception device 100 is started up when a supply of a power supply to the signal reception device 100 is started.

After that, the self-test circuit 30 outputs the test signal TEST and the test execution signal BIST_EN being the signals for the test when the signal reception device 100 is started up (Step S103).

Moreover, in the test mode TSM, the self-test circuit 30 supplies the test execution signal BIST_EN at the high level to the input terminal 143 of the switching circuit 14. As a result, in the switching circuit 14, the input terminal 142 is selected, and the test signal TEST supplied from the self-test circuit 30 is output from the output terminal 144 as the internal signal SS1. That is, to the filter circuit 15, the internal signal SS1 is input. The filter circuit 15 is configured to remove the glitch noise GNZ in a case in which the glitch noise GNZ is contained in the internal signal SS1.

As described before, the test signal TEST is the signal which rises from the low level to the high level and is in the pulse form having the pulse width t1. The filter circuit 15 has the configuration which can remove the glitch noise GNZ. The self-test circuit 30 supplies, to the input terminal 142 of the switching circuit 14, the test signal TEST having the voltage level equivalent to that of the predicted glitch noise GNZ and the pulse width t1.

Moreover, in Step S103, when the self-test circuit 30 outputs the test execution signal BIST_EN at the high level, the self-test circuit 30 outputs the test execution signal DONE at the high level. The test execution signal DONE is supplied to an external device. The test execution signal DONE may be supplied to the function block 20, and the function block 20 may be configured not to receive the processed signal SS2 while the test execution signal DONE at the high level is input.

Then, the self-test circuit 30 acquires the processed signal SS2 from the filter circuit 15 and checks whether or not the filter circuit 15 can remove the glitch noise GNZ. Specifically, the self-test circuit 30 determines whether or not the acquired processed signal SS2 has reached the high level (Step S104). The filter circuit 15 has the configuration capable of removing the pulse signal having a pulse width equal to or shorter than the pulse width t1. That is, the self-test circuit 30 determines that the filter circuit 15 may not remove the glitch noise GNZ in a case in which the processed signal SS2 is at the high level.

In the signal reception device 100, there sometimes occurs a delay in the output signal with respect to the input signal depending on configurations of a circuit and elements. Thus, the self-test circuit 30 determines whether or not a time point T2 at which a certain time t2 has elapsed since a time point T1 at which the supply of the test execution signal BIST_EN at the high level was started is reached (Step S105).

As illustrated in FIG. 5, the test execution signal BIST_EN switches from the high level to the low level at the time point T2. Moreover, the test execution signal DONE similarly switches from the high level to the low level at the time point T2. That is, the self-test circuit 30 operates so as to finish the test mode TSM at the time point T2.

As illustrated in FIG. 4, in Step S105, in a case in which the self-test circuit 30 determines that the time has not reached the time point T2 (in a case of NO in Step S105), the processing returns to Step S104, and the self-test circuit 30 determines whether or not the processed signal SS2 has reached the high level. Moreover, in Step S105, in a case in which the self-test circuit 30 determines that the time has reached the time point T2 (in a case of Yes in Step S105), the self-test circuit 30 determines that the processed signal SS2 at the high level has not been received.

After that, the self-test circuit 30 determines that the portion in the pulse form of the test signal TEST is removed by the filter circuit 15 and hence outputs the non-defective state notification signal PASS (Step S106, see FIG. 5). Moreover, the signal reception device 100 transitions from the test mode TSM to a normal operation state NMM (Step S107, see FIG. 4). Note that the switching from the test mode TSM to the normal operation state NMM can be, for example, a timing at which the test execution signal BIST_EN switches from the high level to the low level, that is, the timing at which the non-defective state notification signal PASS is output.

Moreover, as illustrated in FIG. 6, in a case in which the filter circuit 15 is defective, the processed signal SS2 at the high level is output according to the test signal TEST. That is, when the processed signal SS2 at the high level is detected by the self-test circuit 30 in the test mode TSM, the self-test circuit 30 determines that the filter circuit 15 cannot remove the glitch noise GNZ. That is, in Step S104, in a case in which the self-test circuit 30 determines that the processed signal SS2 is at the high level (in a case of YES in Step S104), the self-test circuit 30 determines that the operation of the filter circuit 15 is defective. Moreover, the self-test circuit 30 detects the processed signal SS2 at the high level and simultaneously outputs the defective state notification signal FAIL at the high level (Step S108, see FIG. 6).

Moreover, the filter circuit 15 cannot certainly remove the glitch noise GNZ, and hence, the self-test circuit 30 cannot accurately convert the input signal AIN to the external output signal DOUT. Thus, the self-test circuit 30 transitions from the test mode TSM to the defective operation state DFM (Step S109). Note that the transition from the test mode TSM to the defective operation state DFM may be executed immediately after the processed signal SS2 is detected to be at the high level or may be executed at a timing at which the test execution signal BIST_EN switches from the high level to the low level.

A description is now given of the defective operation state DFM. The defective operation state DFM varies according to the external device from which the external output signal DOUT is output. For example, in a case in which the external output signal DOUT is a signal to be input to an element which once switches to ON or OFF through the external output signal DOUT and then holds the initial state until a reset signal is independently received, the occurrence of the glitch noise GNZ does not influence the operation. In a case of this configuration, in the defective operation state DFM, only the output of the defective state notification signal FAIL at the high level is executed.

In this defective operation state DFM, for example, a control circuit, not illustrated, including the signal reception device 100 may display, on a display device, not illustrated, the state that the filter circuit 15 of the signal reception device 100 is not normally operating, thereby notifying a user of this state. Moreover, the control circuit, not illustrated, may store, in a storage unit, not illustrated, the device (here, the signal reception device 100) in which the abnormality has occurred, a time, and contents thereof, for example, in association with each other.

Meanwhile, in a case of such a configuration that the external device, not illustrated, malfunctions due to the external output signal DOUT containing the glitch noise GNZ, the signal reception device 100 may consider the state as the defective operation state DFM, hence may stop the operation of the function block 20, and may stop the output of the external output signal DOUT.

As described above, in the signal reception device 100, whether or not the filter circuit 15 normally operates may be determined by executing the test mode TSM when the signal reception device 100 is started up, thereby notifying a result thereof to the outside.

As illustrated in FIG. 5 and FIG. 6, in the signal reception device 100 according to the present embodiment, the test execution signal DONE is configured to be at the high level while the test execution signal BIST_EN is at the high level. However, the configuration is not limited to this example, it is only required that the execution of the test mode is notified to the external device, and hence, the high level may be maintained in such a period that the external device can detect.

Moreover, as illustrated in FIG. 5 and FIG. 6, in the present embodiment, the non-defective state notification signal PASS is the signal in the pulse form, but a signal at the high level may be output for a certain period. Further, the non-defective state notification signal PASS is configured to be output at the timing at which the test execution signal BIST_EN switches from the high level to the low level, but the configuration is not limited to this example. For example, the self-test circuit 30 may determine whether or not the acquired processed signal SS2 is at the high level until a certain period has elapsed since the transition to the test mode TSM regardless of the test execution signal BIST_EN.

The signal reception device 100 configured as described above tests the filter circuit 15 immediately after the signal reception device 100 is started up, hence can accurately convert the input signal AIN to the external output signal DOUT, and can then output the external output signal DOUT to the external device.

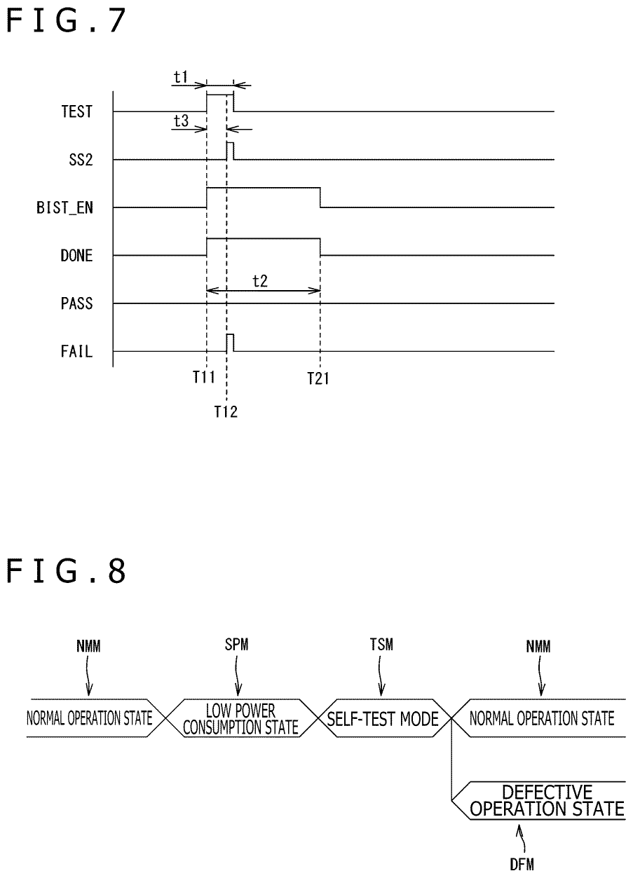

FIG. 7 is a graph for illustrating the state of each signal in a case in which the state is determined to be the defective operation state DFM in the signal reception device 100. FIG. 7 illustrates a case in which a time from a time point T11 to a time point T21 is the test mode.

As described above, the filter circuit 15 has the configuration capable of removing the signal in the pulse form up to the pulse width t1 at the normal operation time. Moreover, it is assumed that the filter circuit 15 is defective and hence can remove a signal in the pulse form having a pulse width equal to or narrower than a pulse width t3 narrower than the pulse width t1.

In the test mode TSM, the self-test circuit 30 supplies the test signal TEST having the pulse width t1 to the switching circuit 14. Moreover, to the filter circuit 15, the processed signal SS2 having the pulse width t1 is input. The filter circuit 15 removes the signal in the pulse form having the pulse width t3. Thus, as illustrated in FIG. 7, of the test signal TEST having the pulse width t1, only a component having the pulse width t3 is removed, and the remaining portion is output as the processed signal SS2.

When the self-test circuit 30 detects that the processed signal SS2 is at the high level at the time point T12, the self-test circuit 30 outputs the defective state notification signal FAIL at the high level.

As described above, even in a case in which the filter circuit 15 is configured to be able to remove a part of the glitch noise GNZ but in a case in which the filter circuit 15 is configured not to be able to remove the entire signal having the estimated pulse width, the signal reception device 100 can determine that the defect is occurring in the filter circuit 15.

With the signal reception device 100 described above, the occurrence of the defect of the filter circuit 15 can quickly be detected. Moreover, it is possible to prevent the external output signal DOUT containing the glitch noise GNZ from being supplied to the external device, thereby being able to suppress instability of a system including the signal reception device 100.

In the present disclosure, the processing circuit 10 is configured to include the filter circuit 15 which removes the glitch noise, but the configuration is not limited to this example. For example, it is possible to widely employ circuits each of which applies determined processing to the input signal such as a band-pass filter circuit which removes a signal having a predetermined frequency and an amplification circuit.

### Modification Example

FIG. 8 is a diagram for illustrating the states of the signal reception device 100 according to a modification example. As illustrated in FIG. 8, in the signal reception device 100, when the state in which the input signal AIN is not input continues for a certain period in the normal operation state NMM, the state transitions to a low power consumption state SPM in which power consumption is limited. The low power consumption state SPM is a state in which such electric power that the signal reception device 100 can be started up when the input signal AIN is input is supplied.

As illustrated in FIG. 8, when the input signal AIN is input to the signal reception device 100 in the low power consumption state SPM, the signal reception device 100 transitions to the test mode TSM. The operation in the test mode TSM is similar to that described before, and hence, details thereof are omitted.

In an electronic circuit such as the signal reception device 100, a large current is likely to flow at a time immediately after the applied voltage is switched, such as a time of the start and a time of the recovery from the low power consumption state SPM. Thus, in the signal reception device 100 in the first modification example, the test model TSM is executed at the start time described before as well as in the period of the recovery to the normal operation state NMM from the low power consumption state SPM.

With this configuration, the frequency of the execution of the test mode TSM increases, and hence, a possibility of the detection of the defect of the filter circuit 15 increases.

In the present disclosure, there is disclosed the configuration that the self-test circuit 30 transitions to the test mode TSM at the start time and at the recovery time from the low power consumption state SPM, but the configuration is not limited to this example. For example, the self-test circuit 30 may execute the test mode TSM at an operation end time or the time of the transition to the low power consumption state SPM. Moreover, the self-test circuit 30 may execute the test mode TSM each time a certain period elapses.

### <Usage>

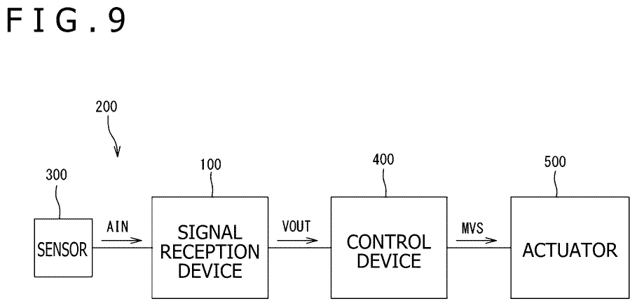

FIG. 9 is a diagram for illustrating a configuration of an example of an electric device 200 including the signal reception device 100. The electric device 200 can include a device which receives a signal from an outside and transmits the received signal to a control unit in a device continuously operated such as an industrial robot and a transport device.

As illustrated in FIG. 9, the electric device 200 includes the signal reception device 100, a sensor 300, a control device 400, and an actuator 500. In the electric device 200, the sensor 300 can include a detection element for detecting a distance to a target within a target region. The sensor 300 measures the distance to the target existing within the target region. The sensor 300 is connected to the input terminal of the signal reception device 100, and the input signal AIN is input from the sensor 300 to the signal reception device 100. Note that the input signal AIN is the analog signal.

The signal reception device 100 applies the digital conversion to the input signal AIN and supplies, to the control device 400, the external output signal DOUT from which the glitch noise has been removed by the filter circuit 15. The control device 400 is the device which controls the electric device 200 and to which the signal reception device 100 and the actuator 500 are connected. The control device 400 outputs a drive signal MVS which drives the actuator 500 on the basis of the external output signal DOUT received from the signal reception device 100. The actuator 500 executes an operation determined by the drive signal MVS.

As described above, in the signal reception device 100, the output of the glitch noise GNZ can be suppressed, and hence, malfunction of the actuator 500 can be suppressed. Note that, in this usage example, as the electric device 200 which employs the signal reception device 100, there is disclosed the configuration which drives the actuator 500 according to the information detected by the sensor 300, but the configuration is not limited to this example. For example, the electric device 200 which employs the signal reception device 100 may include a device which transfers an input signal from an outside to another device.

### <Others>

It should be considered that the embodiment described above is an example in all aspects and is not restrictive. Moreover, the technical scope of the present disclosure is indicated by not the description of the embodiment but the scope of the claims. Further, it should be understood that the technical scope of the present disclosure includes all changes belonging to the meaning and the scope equivalent to the scope of claims.

### APPENDIX

The above-described signal reception device (100) has a configuration (first configuration) including:
a processing circuit (10) configured to output a processed signal (SS2) obtained by applying predetermined processing to a received signal (AIN or TEST);
a function block (20) configured to receive the processed signal (SS2) and execute processing determined on the basis of the processed signal (SS2); and
a self-test circuit (30) configured to output a test signal (TEST) to the processing circuit (10) and to make defective or non-defective state determination according to the signal (SS2) output from the processing circuit (10).

The signal reception device (100) according to the first configuration has a configuration (second configuration) in which the processing circuit (10) includes a filter circuit (15) configured to remove noise (GNZ).

The signal reception device (100) according to the second configuration has a configuration (third configuration) in which
the filter circuit (15) removes glitch noise (GNZ) contained in a received signal, and
the self-test circuit (30) outputs the test signal (TEST) having a pulse width (t1) determined according to the pulse width (t1) of the glitch noise (GNZ) removable by the filter circuit (15).

The signal reception device (100) according to any one of the first to third configurations has a configuration (fourth configuration) in which the self-test circuit (30) has a test mode (TSM) for executing a self-test of causing the test signal (TEST) to be input to the processing circuit (10).

The signal reception device (100) according to the fourth configuration has a configuration (fifth configuration) in which the self-test circuit (30) executes the test mode (TSM) immediately after the signal reception device (100) is started up.

The signal reception device (100) according to the fourth or fifth configuration has a configuration (sixth configuration) in which
the self-test circuit (30) transitions to a low power consumption state (SPM) when a state in which a signal is not input to the processing circuit (10) continues for a certain period, and
the self-test circuit (30) transitions to the test mode (TSM) at a time of recovery from the low power consumption state (SPM).

The signal reception device (100) according to any one of the first to sixth configurations has a configuration (seventh configuration) in which the signal reception device (100) transitions to a normal operation state (NMM) for outputting a non-defective state notification signal (PASS) when the self-test circuit (30) makes the non-defective state determination and transitions to a defective operation state (DFM) for outputting a defective state notification signal (FAIL) when the self-test circuit (30) makes the defective state determination.

The signal reception device (100) according to any one of the first to seventh configurations has a configuration (eighth configuration) in which the processing circuit (10) includes a switching circuit (14) configured to input a signal (SCV) from an outside and the test signal (TEST) and selects any one of the signal (SCV) from the outside and the test signal (TEST).

The above-described IC has a configuration (ninth configuration) that includes the signal reception device (100) according to any one of the first to eighth configurations.

The above-described electric device (200) has a configuration (tenth configuration) that uses the signal reception device (100) according to any one of the first to eighth configurations.

What is claimed is:

1. A signal reception device comprising:
a processing circuit that outputs a processed signal obtained by applying predetermined processing to a received signal;
a function block that receives the processed signal and executes processing determined on a basis of the processed signal; and
a self-test circuit that outputs a test signal to the processing circuit and makes defective or non-defective state determination according to the signal output from the processing circuit.

2. The signal reception device according to claim 1, wherein
the processing circuit includes a filter circuit that removes noise.

3. The signal reception device according to claim 2, wherein
the filter circuit has a configuration that removes glitch noise contained in a received signal, and
the self-test circuit outputs the test signal having a pulse width determined according to the pulse width of the glitch noise removable by the filter circuit.

4. The signal reception device according to claim 1, wherein
the self-test circuit has a test mode for executing a self-test of causing the test signal to be input to the processing circuit.

5. The signal reception device according to claim 4, wherein
the signal reception device transitions to a normal operation state for outputting a non-defective state notification signal when the self-test circuit makes the non-defective state determination and transitions to a defective operation state for outputting a defective state notification signal when the self-test circuit makes the defective state determination.

6. The signal reception device according to claim 4, wherein
the self-test circuit executes the test mode immediately after the signal reception device is started up.

7. The signal reception device according to claim 4, wherein
the self-test circuit transitions to a low power consumption state when a state in which a signal is not input to the processing circuit continues for a certain period, and
the self-test circuit transitions to the test mode at a time of recovery from the low power consumption state.

8. The signal reception device according to claim 1, wherein
the processing circuit includes a switching circuit that receives input of a signal from an outside and the test signal and selects any one of the signal from the outside and the test signal.

9. An integrated circuit comprising:
the signal reception device according to claim 1.

10. An electric device comprising:
the signal reception device according to claim 1.
